(19) United States
(12) Patent Application Publication
(10) Pub. No.: US 2012/0211065 A1
(43) Pub. Date: Aug. 23, 2012

(54) PHOTOELECTRIC CONVERSION DEVICE

(75) Inventors: Shunpei YAMAZAKI, Tokyo (JP); Fumito Isaka, Zama (JP); Jiro Nishida, Atsugi (JP)

(73) Assignee: SEMICONDUCTOR ENERGY LABORATORY CO., LTD., Atsugi-shi (JP)

(21) Appl. No.: 13/398,871

(22) Filed: Feb. 17, 2012

(30) Foreign Application Priority Data
Feb. 21, 2011 (JP) 2011-034642

(51) Int. Cl. H01L 31/075

(52) U.S. Cl. 136/255

(57) ABSTRACT

An object is to provide a photoelectric conversion device in which the amount of light loss due to light absorption in a window layer is small and light efficiency is high. A photoelectric conversion device, having a p-i-n junction, in which a light-transmitting semiconductor with p-type conductivity, a first silicon semiconductor layer with i-type conductivity, and a second silicon semiconductor layer with n-type conductivity are stacked between a pair of electrodes, is formed. The light-transmitting semiconductor layer is formed using an organic compound and an inorganic compound. A high hole-transport material is used for the organic compound, and a transition metal oxide having an electron-accepting property is used for the inorganic compound.

### BACKGROUND OF THE INVENTION

1. Field of the Invention

The present invention relates to a photoelectric conversion device including a window layer formed using an organic compound and an inorganic compound.

2. Description of the Related Art

Recently, a photoelectric conversion device; that generates power without carbon dioxide ejection has attracted attention as a countermeasure against global warming; As typical examples thereof, bulk-type solar cells which use crystalline silicon substrates such as single crystalline and poly crystal line silicon substrates and thin-film type silicon solar cells which use a thin film such as an amorphous silicon film or a microcrystalline silicon film have been known.

In a thin-film type solar cell, a silicon thin film is formed using only a required amount of silicon by a plasma CVD method or the like. The required amount of resources for manufacturing the thin-film solar cells can be smaller than that for manufacturing the bulk-type solar cells and resource saving can be achieved. Further, by using a laser processing method, a screen printing method, or the like, the thin-film solar cells can be easily formed in an integral manner and a large area of solar cells can be easily obtained; thus, manufacturing cost thereof can be reduced. However, the thin-film type silicon solar cells have a disadvantage in lower conversion efficiency than the bulk-type silicon solar cells.

In order to improve conversion efficiency of thin-film type solar cells, a method of using oxide silicon, instead of silicon, for a p-layer serving as a window layer is disclosed (for example, Patent Document 1). A p-layer which is a non-single-crystal silicon based thin film has a light absorption property almost equivalent to that of an i-layer that is a light absorption layer; thus the light loss due to light absorption is caused in the p-layer. According to a technique disclosed in Patent Document 1, silicon oxide having a larger optical band gap than that of silicon is used for a p-layer, so that light absorption in the window layer is suppressed.

In addition, a structure in which an inversion layer which is formed by a field effect is used instead of a p-layer or an n-layer on a window layer side has been suggested. In such a structure, by forming a light-transmitting dielectric or conductor over an n-i or p-i structure, an n-i-p or p-i-n junction can be formed when an electric field is applied. This structure is for the purpose of reducing the light loss due to light absorption in the window layer as much as possible in order to improve light-absorption efficiency in the i-layer.

### REFERENCE

[Patent Document 1] Japanese Published Patent Application No. 1107-130661

### SUMMARY OF THE INVENTION

In a solar cell in which silicon oxide is used for a p-layer serving as a window layer, the light loss due to light absorption in the window layer is reduced, leading to an increase in rate of light which reaches a light absorption layer. However, in silicon oxide having a larger band gap than silicon, resistance is not sufficiently reduced; thus, the loss of current due to resistance is a problem to be solved for further improvement in characteristics.

In addition, a field-effect photoelectric conversion device has many technical difficulties; for example, although a rate of light which reaches the i-layer is increased, relatively high voltage is heeded for formation of the inversion layer. Accordingly, commercialization has not been achieved.

In view of the above problem, an object of one embodiment of the present invention is to provide a photoelectric conversion device in which the amount of light loss due to light absorption in a window layer is small.

One embodiment of the present invention disclosed in this specification relates to a photoelectric conversion device which includes a window layer that is formed using an organic compound and an inorganic compound and that has a high passivation effect on a silicon surface.

One embodiment of the present invention disclosed in this specification is a photoelectric conversion device including, between a pair of electrodes, a light-transmitting semiconductor layer, a first silicon semiconductor layer in contact with the light-transmitting semiconductor layer, and a second silicon semiconductor layer in contact with the first silicon semiconductor layer. The light-transmitting semiconductor layer includes an organic compound and an inorganic compound.

Note that the ordinal numbers such as “first” and “second” in this specification, etc. are assigned in order to avoid confusion among components, but not intended to limit the number or order of the components.

It is preferable that the light-transmitting semiconductor layer have p-type conductivity, the first silicon semiconductor layer have i-type conductivity, and the second silicon semiconductor layer have n-type conductivity.

The first silicon semiconductor layer is preferably non-single-crystal, amorphous, microcrystalline, or polycrystalline.

Another embodiment of the present invention disclosed in this specification is a photoelectric conversion device including, between a pair of electrodes, a first light-transmitting semiconductor layer, a first silicon semiconductor layer in contact with the first light-transmitting semiconductor layer, a second silicon semiconductor layer in contact with the first silicon semiconductor layer, a second light-transmitting semiconductor layer in contact with the second silicon semiconductor layer, a third silicon semiconductor layer in contact with the second light-transmitting semiconductor layer, and a fourth silicon semiconductor layer in contact with the third silicon semiconductor layer. The first and second light-transmitting semiconductor layers each include an organic compound and an inorganic compound.

It is preferable that the first and second light-transmitting semiconductor layers have p-type conductivity, the First and third silicon semiconductor layers have i-type conductivity, and the second and fourth silicon semiconductor layers have n-type conductivity.

The first silicon semiconductor layer is preferably amorphous, and the third silicon semiconductor layer is preferably microcrystalline or polycrystalline.

In the above embodiment of the present invention, for the inorganic compound, an oxide of metal belonging to any of Groups 4 to 8 in the periodic table can be used. In particular, vanadium oxide, niobium oxide, tantalum oxide, chromium oxide, molybdenum oxide, tungsten oxide, manganese oxide, and rhenium oxide, are given.

The organic compound can be selected from an aromatic amine compound, a carbazole derivative, an aromatic hydrocarbon, a high molecular compound, or a heterocyclic compound having a dibenzofuran skeleton or a dibenzothiophene skeleton.

According to one embodiment of the present invention, a photoelectric conversion device in which the amount of light loss due to light absorption in a window layer is small and light efficiency is high can be provided.

### BRIEF DESCRIPTION OF THE DRAWINGS

FIG. 1 is a cross-sectional view illustrating a photoelectric conversion device according to one embodiment of the present invention.

FIGS. 2A and 2B are cross-sectional views each illustrating a photoelectric conversion device according to one embodiment of the present invention.

FIG. 3 is a cross-sectional view illustrating a photoelectric conversion device according to one embodiment of the present invention.

FIGS. 4A to 4D are cross-sectional views illustrating a process of a manufacturing method of a photoelectric conversion device according to one embodiment of the present invention.

FIG. 5 shows the spectral transmission of a light-transmitting semiconductor layer and an amorphous silicon layer arid the spectral sensitivity characteristics of an amorphous silicon photoelectric conversion device.

### DETAILED DESCRIPTION OF THE INVENTION

Hereinafter, embodiments of the present invention will be described in detail with reference to the accompanying drawings. However, the present invention is not limited to the description below, and it is easily understood by those skilled in the art that modes and details disclosed herein can be modified in various ways without departing from the spirit and the scope of the present invention. Therefore, the present invention is not construed as being limited to description of the embodiments. In the drawings for describing the embodiments, the same portions or portions having similar functions are denoted by the same reference numerals, and description of such portions is not repeated in some cases.

### Embodiment 1

In this embodiment, a photoelectric conversion device according to one embodiment of the present invention and a manufacturing method thereof will be described.

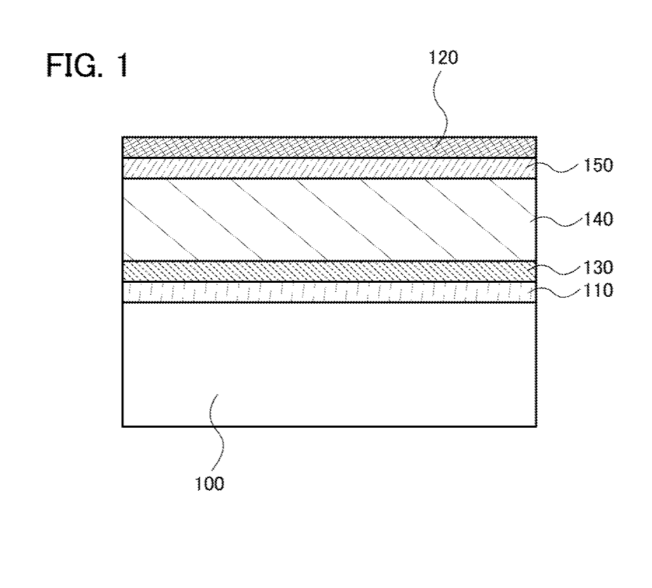

FIG. 1 is a cross-Sectional view of a photoelectric conversion device according to one embodiment of the present invention, in which over a substrate 100, a first electrode 110, a light-transmitting semiconductor layer 130, a first silicon semiconductor layer 140, a second silicon semiconductor layer 150, and a second electrode 120 are stacked in this order. Although a light-receiving surface of the photoelectric conversion device in FIG. 1 is provided on the substrate 100 side, the above order of stacking layers formed over the substrate 100 may be reversed and a light-receiving surface may be provided on the side opposite to the substrate 100.

For the substrate 100, a glass plate of general flat glass, clear flat glass, lead glass, crystallized glass, or the like can be used, for example. Alternatively, a non-alkali glass substrate of aluminosilicate glass, barium borosilicate glass, aluminoborosilicate glass, or the like, or a quartz substrate can be used. In this embodiment, a glass substrate is used as the substrate 100.

Alternatively, a resin substrate can be used as the substrate 100. For example, the following are given: polyether sulfone (PES); polyethylene terephthalate (PET); polyethylene naphthalate (PEN); polycarbonate (PC); a polyamide-based synthetic fiber; polyether etherketone (PEEK); polysulfone (PSF); polyether imide (PEI); polyarylate (PAR); polybutylene terephthalate (PBT); polyimide; an acrylonitrile butadiene styrene resin; poly vinyl chloride; polypropylene; poly vinyl acetate; an acrylic resin, and;the like.

For the first electrode; 110, for example, a light-transmitting conductive film including an indium tin oxide, an indium tin oxide containing silicon, an indium oxide containing zinc, a zinc oxide, a zinc oxide containing gallium, a zinc oxide containing aluminum, a tin oxide, a tin oxide containing fluorine, or a tin oxide containing antimony, etc. can be used. The above light-transmitting conductive film is not limited to a single-layer structure, and a stacked structure of different films may be employed. For example, a stacked layer of ah indium tin oxide arid a zinc oxide containing aluminum, a stacked layer of an indium tin oxide and a tin oxide containing fluorine, etc. can be used. A total film thickness is to be from 10 nm to 1000 nm inclusive.

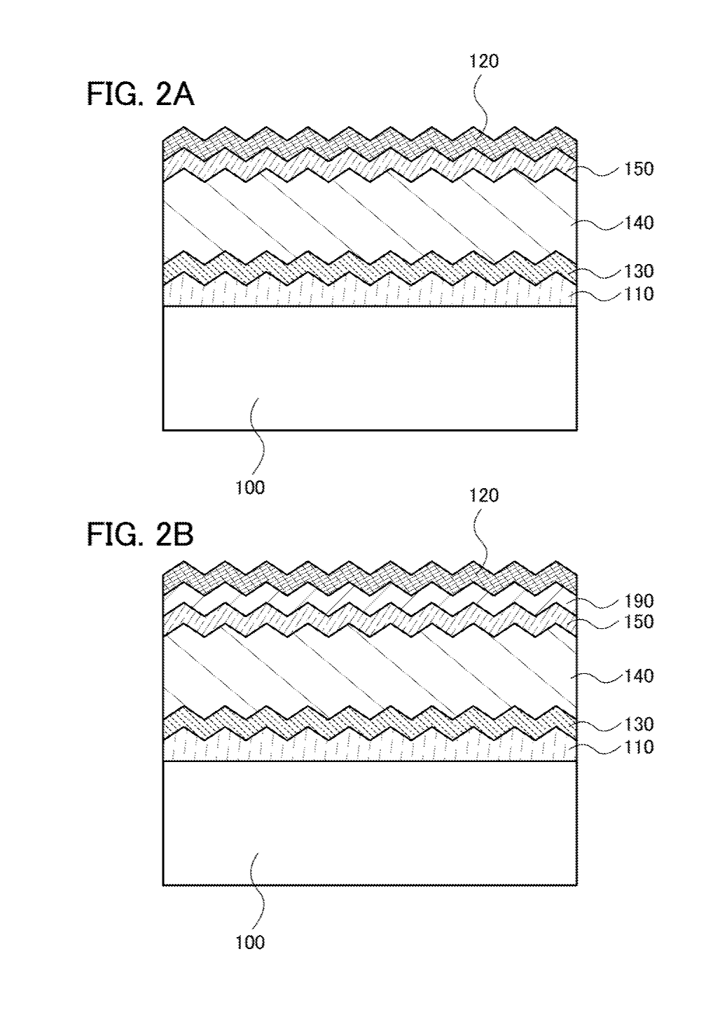

Further, as illustrated in FIG. 2A, a structure in which unevenness is provided in a surface of the first electrode 110 may be employed. When unevenness is provided in the surface of the first electrode 110, unevenness can be formed at each interface of layers stacked over the first electrode 110. The unevenness gives multiple reflection at the substrate surface, an increase in a light pass length in the photoelectric conversion layer, and the total-reflection effect (light trapping effect) in which reflected light by the back surface is totally reflected at the surface, so that the electric characteristics of the photoelectric:conversion device can be improved.

For the second electrode 120, a metal film of aluminum, titanium, nickel, silver, molybdenum, tantalum, tungsten, chromium, copper, stainless steel, or the like can be used. The metal film is not limited to a single-layer structure, and a stacked structure of different films may be employed. For example, a stacked layer of a stainless steel film arid an aluminum film, a stacked layer of a silver film and an aluminum film, or the like can be used. A total film thickness is to be from 100 nm to 600 nm inclusive, preferably from 100 nm to 300 nm inclusive.

Note that as illustrated in FIG. 2B, a light-transmitting conductive film 190 including the above material may be provided between the second electrode 120 and the second silicon semiconductor layer 150. Providing the light-transmitting conductive film 190 enables the number of interfaces where light is reflected to be increased, so that the electric characteristics of the photoelectric conversion device can be improved. Here, the thickness of the light-transmitting conductive film 190 is preferably from 10 nm to 100 nm inclusive. For example, a stacked layer in which indium tin oxide, silver, and aluminum are stacked in this order from the semiconductor layer side can be used. Although the first electrode 110 in FIG; 2B has unevenness, the first electrode 110 may have no unevenness.

The light-transmitting semiconductor layer 130 is formed Using a composite material of an inorganic compound and an organic compound. As the inorganic compound, transition metal oxide can be used. Among the transition metal oxide, an oxide of a metal belonging to any of Groups 4 to 8 in the periodic table is particularly preferable. Specifically, vanadium oxide, niobium oxide, tantalum oxide, chromium oxide, molybdenum oxide, tungsten oxide, manganese oxide, arid rhenium oxide, or the like can be used. Among these, molybdenum oxide is especially preferable since it is stable in, the air and its hygroscopic property is low so that it can be easily treated.

As the organic compound, any of a variety of compounds such as an aromatic amine compound, a carbazole derivative, an aromatic, hydrocarbon, a high molecular compound (e.g., oligomer, dendrimer, or polymer), and a heterocyclic compound having a dibenzofuran skeleton or a dibenzothiophene skeleton can be used. Note that the organic compound used for the composite material is preferably an organic compound having a high hole-transport property. Specifically, a substance having a hole mobility of 10⁻⁶ cm²/Vs or higher is preferably used. However, other substances than the above described materials may also be used as long as the substances have higher hole-transport properties than electron-transport properties.

The transition metal oxide has an electron-accepting property. A composite material of an organic, compound having a high hole-transport property and such a transition metal has high carrier density and exhibits p-type semiconductor characteristics. The composite: material has high transmittance of light in a wide wavelength range from visible light region to infrared region.

The composite material is stable, and silicon oxide is not generated at an interface between the silicon layer arid the composite material; thus, defects at the interface can be reduced, resulting in improvement in lifetime of carriers.

In the case where the composite material is formed as a passivation film on both of surfaces (a surface and a back surface) of an n-type single crystal silicon substrate, the following has been confirmed by the experiment; the lifetime of carriers is 700 μsec or more when 4-phenyl-4′-(9-phenylfluoren-9-yl)triphenylamine (abbreviation: BPAFLP) and molybdenum(VI) oxide are used as the organic compound and the inorganic compound respectively; the lifetime; of carriers is 400 μsec or more when 4,4′-bis[N-(1-naphthyl)-N-phenylamino]biphenyl (abbreviation: NPB) and molybdenum(VI) oxide are used as the organic compound and the inorganic compound respectively. Note that the lifetime of carriers in the case where an n-type single crystal silicon substrate-is not provided with a passivation film is about 40 μsec, and the lifetime of carriers in the case where indium tin oxide (ITO) is formed on both of surfaces of the single crystal silicon substrate by a sputtering method is about 30 μsec.

For the first silicon semiconductor layer 140, an i-type silicon semiconductor is used. Note that in this specification, an i-type semiconductor refers to not only a so-called intrinsic semiconductor in which the Fermi level lies in the middle of the band gap, but also a semiconductor in which the concentration of an impurity imparting p-type or n-type conductivity is lower than or equal to 1×10²⁰ cm⁻³ and the photoconductivity is 100 times or more as high as the dark conductivity. This i-type silicon semiconductor may include an element belonging to Group 13 or Group 15 in the periodic table as an impurity element.

For the i-type silicon semiconductor used in the first silicon semiconductor layer 140, it is preferable to use non-single-crystal silicon, amorphous silicon, microcrystalline silicon, or poly crystal line silicon. Amorphous silicon has a peak of Spectral sensitivity in the visible light region; thus, with use of amorphous silicon, a photoelectric conversion device having a high photoelectric conversion ability in an environment with low illuminance such as a place under a fluorescent lamp can be formed. Further, microcrystalline silicon and polycrystalline silicon each have a peak of spectral sensitivity on the longer wavelength side than the visible light region; thus, with use of microcrystalline silicon or polycrystalline silicon, a photoelectric conversion device having a high photoelectric conversion ability in the outdoors where a light source is sunlight can be formed. The thickness of the first silicon semiconductor layer 140 in the case of using amorphous silicon is preferably from 100 nm to 600 nm inclusive, and the thickness in the ease of using; microcrystalline silicon or polycrystalline silicon is preferably from 1 μm to 100 μm inclusive.

For the second silicon semiconductor layer 150, an n-type silicon semiconductor film is used. Note that the thickness of the second silicon semiconductor layer 150 is preferably from 3 nm to 50 nm inclusive. Furthermore, although amorphous silicon can be used for the second silicon semiconductor layer 150, microcrystalline silicon or polycrystalline silicon that has lower resistance than amorphous silicon is preferably used.

By stacking the above described p-type light-transmitting semiconductor layer 130, i-type first silicon semiconductor layer 140, and n-type second silicon semiconductor layer 150, a p-i-n junction can be formed.

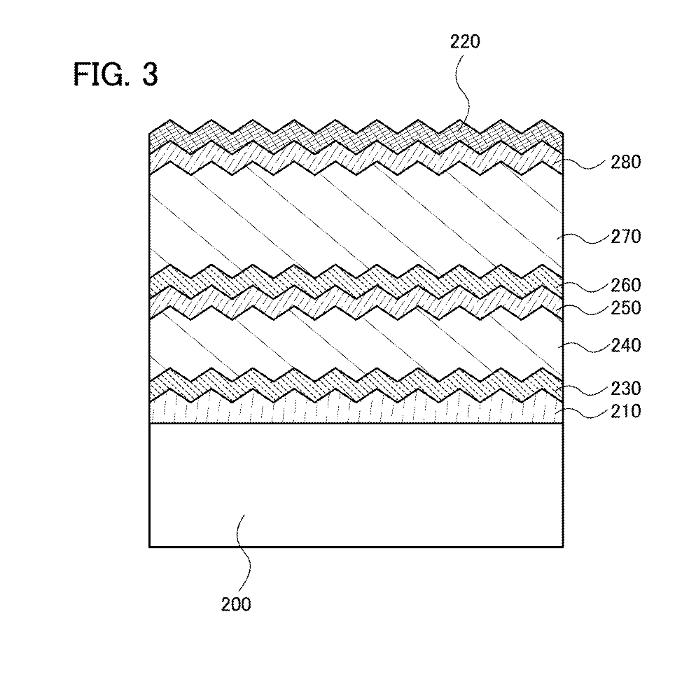

Further, as illustrated in FIG 3, a structure in which over a substrate 200, a first electrode 210, a first light-transmitting semiconductor layer 230, a first silicon semiconductor layer 240, a second silicon semiconductor layer 250, a second light-transmitting semiconductor layer 260, a third silicon semiconductor layer 270, a fourth silicon semiconductor layer 280, and a second electrode 220 are provided may be employed. The photoelectric conversion device having the above structure is a so-called tandem photoelectric conversion device in which a top cell where the first silicon semiconductor layer 240 functions as a light absorption layer and a bottom cell where the third silicon semiconductor layer 270 functions as a light absorption layer are connected in series.

In the photoelectric conversion device in FIG. 3, amorphous silicon is used for the first silicon semiconductor layer 240 and microcrystalline silicon or polycrystalline silicon is used for the third silicon semiconductor layer 270. Further, for the first light-transmitting semiconductor layer 230 and the second light-transmitting semiconductor layer 260, a material similar to that of the light-transmitting semiconductor layer 130 can be used, and for the second silicon semiconductor layer 250 and the fourth silicon semiconductor layer 280, a material similar to that of the second silicon semiconductor layer 150 can be used.

When light enters the top cell through the first electrode 210 from the substrate 200 side, in the first silicon semiconductor layer 240, light which is mainly in the visible light region or on the shorter wavelength side than the visible light region is converted into electric energy. Then, in the third silicon semiconductor layer 270, the light which is mainly on the longer wavelength side than the visible light region and has passed through the top cell is converted into electric energy. Therefore, light with wide wavelength range can be efficiently used, and thus the conversion efficiency of the photoelectric conversion device can be improved.

In conventional photoelectric conversion devices, amorphous silicon or microcrystalline silicon whose resistance is lowered by addition of impurities, or the like is used for a window layer; thus, the window layer has a light absorption property equivalent to that of the light/absorption layer. Although photo-carriers are generated in the window layer, the lifetime of minority carrier is short and the carriers cannot be taken out as current. Thus, the light absorption in the window layer is a heavy loss in the conventional photoelectric conversion devices,

According to one embodiment of the present invention, the p-type light-transmitting semiconductor layer formed using a composite material of an inorganic compound and an organic compound is used as a window layer, whereby the light loss due to light absorption in the window layer is reduced and photoelectric conversion can be efficiently performed in the i-type light absorption layer. In addition, as described above, the composite material has extremely high passivation effect on the silicon surface. Accordingly, the photoelectric conversion efficiency of the photoelectric conversion device can be improved.

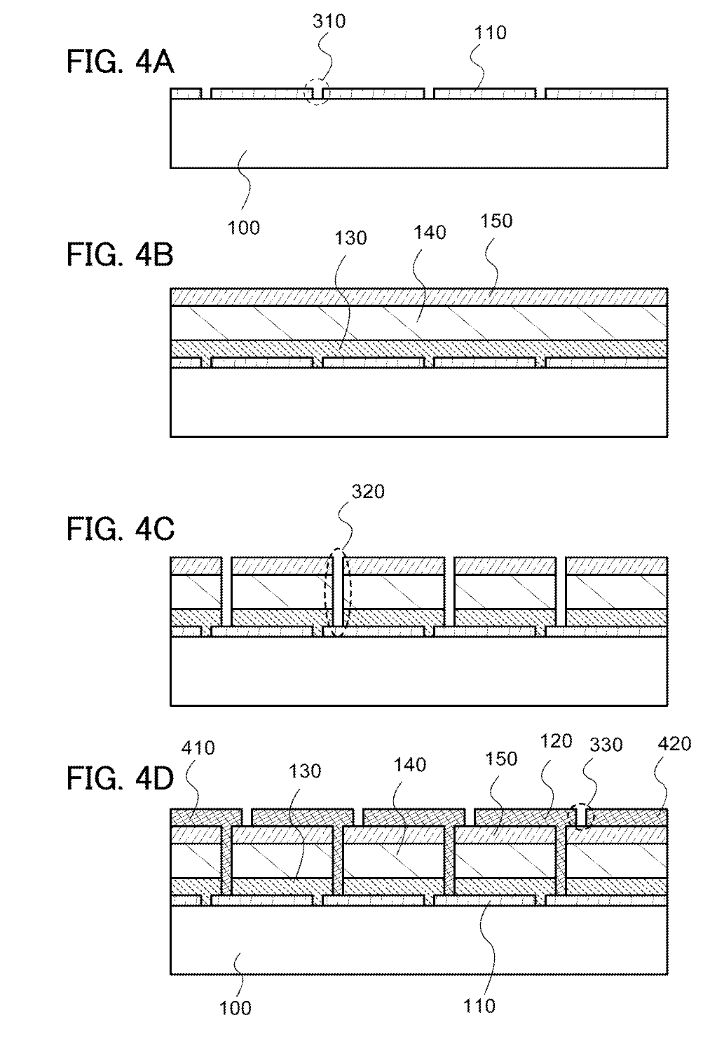

Next, a manufacturing method of the photoelectric conversion device according to one embodiment of the present invention will be described with reference to FIGS. 4A to 4D. The manufacturing method of the photoelectric conversion device described below is a manufacturing method of an integrated photoelectric conversion device in which a plurality of photoelectric conversion devices illustrated in FIG. 1 are connected in series, and the completed structure is illustrated in FIG. 4D.

First, a light-transmitting conductive film serving as the first electrode 110 is formed over the substrate 100. Here, an indium tin oxide (ITO) film is formed, to a thickness of 100 nm by a sputtering method. Note that unevenness of the light-transmitting conductive film illustrated in FIGS. 2A and 2B can be easily formed by, for example, etching a zinc-oxide-based light-transmitting conductive film using strong acid such as hydrochloric acid.

Although a glass substrate is used as the substrate 100 in this embodiment, if a resin substrate with a thickness of about 100 μm for example is used, roll-to-roll processing can be performed.

The roll-to-roll processing includes a step using a screen printing method, a laser processing method, or the like, in addition to a film formation step using a sputtering method, a plasma CVD method, or the liked. Accordingly, almost the whole process for manufacturing a photoelectric conversion device can be covered by roll-to-roll processing. Alternatively, some of steps for the manufacturing process may be performed with roll-to-roll processing; a step of division into sheet forms may be performed; and the latter steps for the manufacturing; step may be individually performed for each sheet. For example, by attaching each piece of the divided sheet to a frame that is formed of ceramic, metal, a composite body thereof, or the like, it can be handled in the same manner as a glass substrate or the like.

Next, a first isolation groove 310 which divides the light-transmitting conductive film into a plurality of pieces is formed (see FIG. 4A). The isolation grooves can be formed by laser processing or the like. As a laser used for this laser processing, a continuous wave laser or a pulsed laser which emits light in a visible light region or an infrared light region is preferably used. For example, a fundamental wave (wavelength: 1064 nm) or a second harmonic (wavelength: 532 nm) of an Nd-YAG laser can be used. Note that here, a part of the isolation grooves may reach the substrate 100. Also, the light-transmitting conductive film is divided in this step, whereby the first electrode 110 is formed.

Next, the light-transmitting semiconductor layer 130 is formed over the first electrode: 110 and the first isolation groove 310. The light-transmitting semiconductor layer 130 is formed using the above inorganic: compound and organic compound by a co-deposition method. Note that a co-deposition method is a method in which vapor deposition from a plurality of evaporation sources is performed at the same time in one deposition chamber. It is preferable that deposition be performed in high vacuum. The high vacuum can be obtained by evacuation of the deposition chamber with an evacuation unit to a vacuum of about 5×10⁻³ Pa or less, preferably, about 10⁻⁴ Pa to 10⁻⁶ Pa.

In this embodiment, the light-transmitting semiconductor layer 130 is formed by co-depositing 4-phenyl-4′-(9-phenylfluoren-9-yl)triphenylamine (abbreviation: BPAFLP) and molybdenum(VI) oxide. The thickness of the light-transmitting semiconductor layer 130 is set to 50 nm, and the weight ratio of BPAFLP to molybdenum oxide is controlled to be 2:1 (=BPAFLP:molybdenum oxide).

Next, by a plasma CVD method, an i-type amorphous silicon film is formed with a thickness of 600 nm as the first silicon semiconductor layer 140. As a source gas, silane or disilane can be used, and hydrogen may be added thereto. At this time, an atmospheric component contained in the layer serves as a donor in some cases; thus, boron (B) may be added to the source gas so that the conductivity type is closer to i-type. In that case, the concentration of boron in the i-type amorphous silicon is controlled to higher than or equal to 0.001 at. % and lower than or equal to 0.1 at. %.

Next, as the second silicon semiconductor layer 150, a 30-nm-thick n-type microcrystalline silicon layer is formed (see FIG. 4B). In this embodiment, a doping gas containing an impurity imparting n-type conductivity is mixed into a source gas, and an n-type microcrystalline silicon film is formed by a plasma CVD method. As the impurity imparting n-type conductivity, typically, phosphorus, arsenic, or antimony which is an element belonging to Group 15 in the periodic table, or the like is typically given. For example, a doping gas such as phosphine is mixed into a source gas such as silane, so that an n-type microcrystalline silicon layer can be formed. Note that although the second silicon semiconductor layer 150 may be formed using amorphous silicon, it is preferably formed using microcrystalline silicon which has lower resistance.

Next, a second isolation groove 320 which divides a stacked layer of the light-transmitting semiconductor layer 130, the first silicon semiconductor layer 140, and the second silicon semiconductor layer 150 into a plurality of pieces is formed (see FIG. 4C). The isolation grooves can be formed by laser processing or the like. As a laser used in this laser processing, a continuous wave laser or a pulsed laser which emits light in a visible light region is preferably used. For example, a second harmonic (wave length: 532 nm) or the like of an Nd-YAG laser can be used. Note that in the ease where the light-transmitting conductive film is provided as illustrated in FIG. 2B, the light-transmitting conductive film may be formed over the second silicon semiconductor layer 150 before the second isolation groove 320 is formed.

Next, a conductive film is formed in such a manner that the conductive film fills the second isolation groove 320 arid covers the second silicon semiconductor layer 150. Here, a silver film with a film thickness of 5 nm and an aluminum film with a filth thickness of 300 nm are stacked in this order by a sputtering method.

Then, a third isolation groove 330 which divides the conductive film into a plurality of pieces is formed (see FIG. 4D). The isolation grooves can be formed by laser processing or the like. As a laser used for this laser processing, a continuous wave laser or a pulsed laser which emits light in an infrared light region is preferably used. For example, a fundamental wave (wavelength: 1064 nm) or the like of an Nd-YAG laser can be used. Further, by dividing the conductive film in this step, the second electrode 120, a first terminal 410, and a second terminal 420 are formed. The first terminal 410 and the second terminal 420 each serve as an extraction electrode.

In the above manner, the photoelectric conversion device according to one embodiment of the present invention can be manufactured. Note that the manufacturing method of the integrated structure including the photoelectric conversion devices illustrated in FIG, 1 is described in this embodiment; however, the photoelectric conversion devices with the structures of FIGS. 2A and 2B and FIG. 3 may be integrated in a manner similar to the above.

This embodiment can be implemented in appropriate combination with the structures described in the other embodiments.

### Embodiment 2

In this embodiment, the light-transmitting semiconductor layer described in Embodiment 1 will be described.

For each of the light-transmitting semiconductor layers 130, 230, and 260 in the photoelectric conversion devices described in Embodiment 1, a composite material of a transition metal oxide and an organic compound can be used. Note that in this specification, the word “composite” means not only a state in which two materials are simply mixed but also a state in which a plurality of materials are mixed and charges are transferred between the materials.

As the transition metal oxide, a transition metal oxide having an electron-accepting property can be used. Specifically, among transition metal oxides, an oxide of a metal belonging to any of Groups 4 to 8 of the periodic table is preferable. In particular, it is preferable to use vanadium oxide, niobium oxide tantalum oxide, chromium oxide, molybdenum oxide, tungsten oxide, manganese oxide, or rhenium oxide because of their high electron-accepting properties. Among these, molybdenum oxide is especially preferable since it is stable in the air and its hygroscopic property is low arid so that it can be easily treated.

As the organic compound, any of a variety of compounds such as an aromatic amine compound, a carbazole derivative, an aromatic hydrocarbon, a high molecular compound (e.g., an oligomer, a dendrimer, or a polymer), and a heterocyclic compound having a dibenzofuran skeleton or a dibenzothiophene skeleton can be used. As the organic compound used for the composite material, an organic compound having a high hole-transport property is used. Specifically, a substance having a hole mobility of 10⁻⁶ cm²/Vs or higher is preferably used. However, any other substance whose hole-transport property is higher than the electron-transport property may be used.

In a composite material of the above-described transition metal oxide and the above-described organic compound, electrons in the highest occupied molecular orbital level (HOMO level) of the organic compound are transferred to the conduction band of the transition metal oxide, whereby interaction between; the transition metal oxide and the organic compound occurs. Due to this interaction, the composite material including the transition metal oxide and the organic compound has high carrier density and has p-type semiconductor characteristics.

The organic compounds which can be used in the composite material will be specifically given below.

As the aromatic amine compounds that can be used for the composite material, the following can be given as examples: 4,4′-bis[N-(1-naphthyl)-N-phenylamino]biphenyl (abbreviation: NPB); N,N′-bis(3-methylphenyl-N,N′-diphenyl-[1,1′-biphenyl]-4,4′-diamine (abbreviation: TPD); 4,4′,4″-tris(N,N-diphenylamino)triphenylamine (abbreviation: TDATA); 4,4′,4″-tris[N-(3-methylphenyl)-N-phenylamino]triphenylamine (abbreviation: MTDATA); and N,N′-bis(spiro-9,9′-bifluoren-2-yl)-N,N′-diphenylbenzidine (abbreviation: BSPB). In addition, the following can be given: N,N′-bis(4-methylphenyl)-N,N′-diphenyl-p-phenylenediamine (abbreviation: DTDPPA); 4,4′-bis[N-(4-diphenylaminophenyl)-N-phenylamino]biphenyl (abbreviation: DPAB); N,N′-bis [4-[bis(3-methylphenyl)amino]phenyl]-N,N′-diphenyl-[1,1′-biphenyl]-4,4′-diamine (abbreviation: DNTPD); 1,3,5-tris[N-(4-diphenylaminophenyl)-N-phenylamino]benzene (abbreviation; DPA3B); 4-phenyl-4′-(9-phenylfluoren-9-yl)triphenylamine (abbreviation: BPAFLP); and 4,4′-bis[N-(9,9-dimethylfluoren-2-yl)-N-phenylamino]biphenyl (abbreviation: DFLDPBi).

As carbazole derivatives which can be used for the composite material, the following can be given specifically: 3-[N-(9-phenylcarbazol-3-yl)-N-phenylamino]-9-phenylcarbazole (abbreviation: PCzPCA1); 3,6-bis[N-(9-phenylcarbazol-3-yl)-N-phenylamino]-9-phenylcarbazole (abbreviation: PCzPCA2); 3-[N-(1-naphthyl)-N-(9-phenylcarbazol-3-yl)amino]-9-phenylcarbazole (abbreviation: PCzPCN1); and the like.

Moreover, as a carbazole derivative which cart be used for the composite material, 4,4′-di(N-carbazolyl)biphenyl (abbreviation: CBP), 1,3,5-tris[4-(N-carbazolyl)phenyl]benzene (abbreviation: TCPB), 9-[4-(N-carbazolyl) phenyl]-10-phenylanthracene (abbreviation: CzPA), 1,4-bis[4-(N-carbazolyl)phenyl]-2,3,5,6-tetraphenylbenzene, or the like can be used.

As aromatic hydrocarbon that can be used for the composite material, the following can be given as examples: 2-tert-butyl-9,10-di(2-naphthyl)anthracene (abbreviation: t-BuDNA); 2-tert-butyl-9,10-di(1-naphthyl)anthracene; 9,10-bis(3,5-diphenylphenyl)anthracene (abbreviation: DPPA); 2-tert-butyl-9,10-bis(4-phenylphenyl)anthracene (abbreviation: t-BuDBA); 9,10-di(2-naphthyl)anthracene (abbreviation; DNA); 9,10-diphenylanthracene (abbreviation: DPAnth); 2-tert-butylanthracene (abbreviation: t-BuAnth); 9,10-bis(4-methyl-1-naphthyl)anthracene (abbreviation: DMNA); 9,10-bis[2-(1-naphthyl)phehyl]-2-tert-butylanthracene; 9,10-bis[2-(1-naphthyl)phenyl]anthracene; 2,3,6,7-tetramethyl-9,10-di(1-naphthyl)anthracene; 2,3,6,7-tetramethyl-9,10-di(2-naphthyl)anthracene; 9,9′-bianthryl; 10,10′-diphenyl-9,9′-bianthryl; 10,10′-bis(2-phenylphenyl)-9,9′-bianthryl; 10,10′-bis[(2,3,4,5,6-pentaphenyl)phenyl]-9,9′-bianthryl; anthracene; tetracene; rubrene; perylene; 2,5,8,11-tetra(tert-butyl)perylene; and the like. Besides those, pentacene, coronene, or the like cart also be used. The aromatic hydrocarbon which has a hole mobility of 1×10⁻⁶ cm²/Vs or higher and which has 14 to 42 carbon atoms is particularly preferable.

The aromatic hydrocarbon which can be used for the composite material may have a vinyl skeleton. As the aromatic hydrocarbon having a vinyl group, the following are given for example: 4,4′-bis(2,2-diphenylvinyl)biphenyl (abbreviation: DPVBi); 9,10-bis[4-(2,2-diphenylvinyl)phenyl]anthracene (abbreviation: DPVPA); and the like.

The organic compound used for the composite material may be a heterocyclic compound having a dibenzofuran skeleton or a dibenzothiophene skeleton.

The organic compound that can be used for the composite material may be a high molecular compound, and the following can; be given as examples: poly(N-vinylcarbazole) (abbreviation: PVK); poly(4-vinyltriphenylamine) (abbreviation: PVTPA); poly[N-(4-{N′-[4-(4-diphenylamino)phenyl]phenyl-N′-phenylamino}phenyl)methacrylamide] (abbreviation: PTPDMA); poly[N,N′-bis(4-butylphenyl)-N,N′-bis(phenyl)benzidine] (abbreviation: Poly-TPD); and the like.

The light-transmitting semiconductor layer described in this embodiment has excellent light-transmitting property with respect to light in a wavelength range which is absorbed by amorphous silicon, microcrystalline silicon, or polycrystalline silicon. Thus, the light-transmitting semiconductor layer can be formed thick as compared with the thickness of the silicon semiconductor layer in which case it is used for the window layer and thus the resistance loss can be reduced.

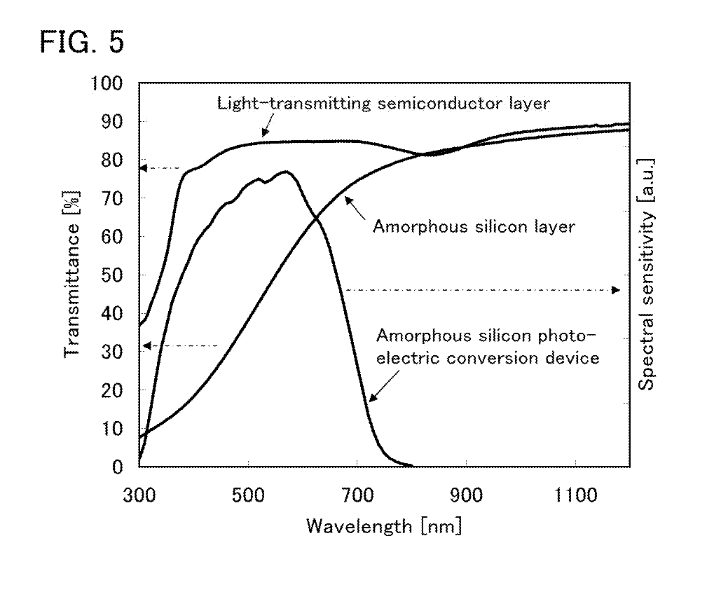

FIG. 5 shows the spectral transmissions of a light-transmitting semiconductor layer (with a thickness of 57 nm) and an amorphous silicon layer (with a thickness of 10 nm) and the spectral sensitivity characteristics of the; general amorphous silicon photoelectric conversion device. The light-transmitting semiconductor layer is obtained by co-deposition of 4-phenyl-4′-(9-phenylfluoren-9-yl)triphenylamine (abbreviation: BPAFLP) and molybdenum(VI) oxide. As shown in FIG. 5, whereas the light-transmitting semiconductor layer in this embodiment has high light-transmitting transmittance in the wide wavelength range, the amorphous, silicon layer has high absorbance of light on the shorter wavelength side than that of the visible light. For example, in the case of the conventional photoelectric conversion device in which an amorphous silicon film is used for the window layer, absorption of light on the shorter wavelength side than the visible light is a loss. On the other hand, in the case of using the light-transmitting semiconductor layer for the window layer, light in the wavelength range, which is absorbed by an amorphous silicon film, can be efficiently used for photoelectric con version.

A variety of methods can be used for forming the light-transmitting semiconductor layer, whether the method is a dry process or a wet process. As a dry method, a co-deposition method, by which a plurality of evaporation materials are vaporized from a plurality of evaporation sources to perform deposition, and the like are given as examples. As a wet method, a composition having a composite material is adjusted by a sol-gel method or the like, arid deposition can be performed using an ink-jet method or a spin-coating method.

When the above-described light-transmitting semiconductor layer is used for a window layer of a photoelectric conversion device, the light joss caused by light absorption in the window layer is reduced, and the electric characteristics of the photoelectric conversion device can be improved.

This embodiment can be implemented in appropriate combination with the structures described in the other embodiments.

This application is based on Japanese Patent Application serial no. 2011-034642 filed with Japan Patent Office on Feb. 21, 2011, the entire contents of which are hereby incorporated by reference.

What is claimed is:

1. A photoelectric conversion device comprising:
a first electrode;
a light-transmitting semiconductor layer over the first electrode;
a first silicon semiconductor layer over the light-transmitting semiconductor layer;
a second silicon semiconductor layer over the first silicon semiconductor layer; and
a second electrode over the second silicon semiconductor layer,
wherein the light-transmitting semiconductor layer includes an organic compound and an inorganic compound.

2. The photoelectric conversion device according to claim 1, wherein the light-transmitting semiconductor layer has p-type conductivity, the first silicon semiconductor layer has i-type conductivity, and the second silicon semiconductor layer has n-type conductivity.

3. The photoelectric conversion device according to claim 1, wherein the first silicon semiconductor layer comprises a material in one of non-single-crystal state, amorphous state, microcrystalline state, and polycrystalline state.

4. The photoelectric conversion device according to claim 1, wherein the photoelectric conversion device is formed on a substrate made from glass.

5. The photoelectric conversion device according to claim 1, wherein the photoelectric conversion device is formed on a substrate made from resin.

6. A photoelectric conversion device comprising:
a first electrode;
a first light-transmitting semiconductor layer over the first electrode;
a first silicon semiconductor layer over the first light-transmitting semiconductor layer;
a second silicon semiconductor layer over the first silicon semiconductor layer;
a second light-transmitting semiconductor layer over the second silicon semiconductor layer;
a third silicon semiconductor layer over the second light-transmitting semiconductor layer;
a fourth silicon semiconductor layer over the third silicon semiconductor layer; and
a second electrode over the fourth silicon semiconductor layer,
wherein the first light-transmitting semiconductor layer and the second light-transmitting semiconductor layer each include an organic compound and an inorganic compound.

7. The photoelectric conversion device according to claim 6, wherein the first and second light-transmitting semiconductor layers each have p-type conductivity, the first and third silicon semiconductor layers each have i-type conductivity, and the second and fourth silicon semiconductor layers each have n-type conductivity.

8. The photoelectric conversion device according to claim 6, wherein the first silicon semiconductor layer is amorphous, and the third silicon semiconductor layer is microcrystalline or polycrystalline.

9. The photoelectric conversion device according to claim 6, wherein the inorganic compound is an oxide of a metal belonging to any of Group 4 to Group 8 in the periodic table.

10. The photoelectric conversion device according to claim 6, wherein the inorganic compound is selected from a vanadium oxide, a niobium oxide, a tantalum oxide, a chromium oxide, a molybdenum oxide, a tungsten oxide, a manganese oxide, or a rhenium oxide.

11. The photoelectric conversion device according to claim 6, wherein the organic compound is selected from an aromatic amine compound, a carbazole derivative, an aromatic hydrocarbon, a high molecular compound, or a heterocyclic compound having a dibenzofuran skeleton or a dibenzothiophene skeleton.

12. The photoelectric conversion device according to claim 6, wherein the photoelectric conversion device is formed on a substrate made from glass.

13. The photoelectric conversion device according to claim 6, wherein the photoelectric conversion device is formed on a substrate made from resin.

14. A photoelectric conversion device comprising:
a plurality of first electrodes;
a light-transmitting semiconductor layer over the plurality of first electrodes;
a first silicon semiconductor layer over the light-transmitting semiconductor layer;
a second silicon semiconductor layer over the first silicon semiconductor layer; and
a plurality of second electrodes over the second silicon semiconductor layer,
wherein the light-transmitting semiconductor layer includes an organic compound and an inorganic compound,
wherein a plurality of isolation grooves are formed in a stacked structure of the light-transmitting semiconductor layer, the first silicon semiconductor layer, and the second silicon semiconductor layer, and
wherein each one of the plurality of first electrodes is electrically connected to a corresponding one of the plurality of second electrodes through a corresponding one of the plurality of isolation grooves.

15. The photoelectric conversion device according to claim 14, wherein the light-transmitting semiconductor layer has p-type conductivity, the first silicon semiconductor layer has i-type conductivity, and the second silicon semiconductor layer has n-type conductivity.

16. The photoelectric conversion device according to claim 14, wherein the first silicon semiconductor layer comprises a material in one of non-single-crystal state, amorphous state, microcrystalline state, and polycrystalline:state.

17. The photoelectric conversion device according to claim 14, wherein the photoelectric conversion device is formed on a substrate made from glass.

18. The photoelectric conversion device according to claim 14, wherein the photoelectric conversion device is formed on a substrate made from a resin.
